(19) United States
(12) Patent Application Publication
(10) Pub. No.: US 2026/0020262 A1
(43) Pub. Date: Jan. 15, 2026

(54) SEMICONDUCTOR DEVICE

(71) Applicant: United Microelectronics Corp., Hsinchu (TW)

(72) Inventors: Chien-Yi LEE, Hsinchu City (TW); Chun-Liang CHENG, Hsinchu City (TW); Chih-Hsien HUANG, Yunlin County (TW); Yi-Chin LI, Hualien County (TW); Sheng-Huei DAI, Taitung County (TW)

(21) Appl. No.: 18/804,144

(22) Filed: Aug. 14, 2024

(30) Foreign Application Priority Data
Jul. 9, 2024 (TW) 113125644

(51) Int. Cl. H01L 29/94; H01L 29/43; H03F 3/04

(52) U.S. Cl. CPC H10D 1/66; H10D 64/605; H03F 3/04

(57) ABSTRACT

A semiconductor device including a resistor and a capacitor is provided. The capacitor includes a top electrode and a bottom electrode. The semiconductor device further includes a substrate, a first well, at least two doped regions, at least one gate and at least one oxide layer. The substrate serves as the bottom electrode of the capacitor. The first well is disposed in the substrate. The doped regions are disposed in the first well and are connected to the ground. The gate is disposed in the substrate and serves as the resistor and the top electrode of the capacitor. The oxide layer is disposed between the gate and the substrate.

This application claims the benefit of Taiwan application Serial No. 113125644, filed Jul. 9, 2024, the subject matter of which is incorporated herein by reference.

### BACKGROUND OF THE INVENTION

### Field of the Invention

The invention relates in general to a semiconductor device, and more particularly to a semiconductor device having capacitor.

### Description of the Related Art

Single-stage field-effect transistor amplifier has been widely used in the field of electronic products. Common-gate amplifier, one of the single-stage field-effect transistors is normally used as a current buffer or voltage amplifier. In the circuit of a common-gate amplifier, the source of a transistor is used as input and the drain is used as an output; the gate is connected to some DC biasing voltages and is connected to the ground, that is, an AC ground. Generally speaking, the common-gate amplifier includes a large-sized capacitor and has a larger size.

### SUMMARY OF THE INVENTION

The invention is directed to a semiconductor device having a smaller size because the semiconductor device not only has a small-sized capacitor, but further integrates capacitor and resistor.

According to one embodiment of the present invention, a semiconductor device including a resistor and a capacitor is provided. The capacitor includes a top electrode and a bottom electrode. The semiconductor device further includes a substrate, a first well, at least two doped regions, at least one gate and at least one oxide layer. The substrate serves as the bottom electrode of the capacitor. The first well is disposed in the substrate. The doped regions are disposed in the first well and are connected to the ground. The gate is disposed in the substrate and serves as the resistor and the top electrode of the capacitor. The oxide layer is disposed between the gate and the substrate.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is an equivalent circuit diagram of a semiconductor device according to an embodiment of the present invention.

FIG. 2A is a top view of a semiconductor device according to an embodiment of the present invention.

FIG. 2B is a cross-sectional view along the connection line 2B-2B′ of FIG. 2A.

FIG. 2C is a cross-sectional view along the connection line 2C-2C′ of FIG. 2A.

FIG. 3A is a top view of a semiconductor device according to another embodiment of the present invention.

FIG. 3B is a cross-sectional view along the connection line 3B-3B′ of FIG. 3A.

### DETAILED DESCRIPTION OF THE INVENTION

A number of embodiments are exemplified below. It should be noted that although the present disclosure does not illustrate all possible embodiments, other embodiments not disclosed in the present disclosure are still applicable. Moreover, the dimension scales used in the accompanying drawings are not based on actual proportion of the product. Therefore, the specification and drawings are for explaining and describing the embodiment only, not for limiting the scope of protection of the present disclosure. Furthermore, descriptions of the embodiments, such as detailed structures, manufacturing procedures and materials, are for exemplification purpose only, not for limiting the scope of protection of the present disclosure. Suitable modifications or changes can be made to the structures and procedures of the embodiments to meet actual needs without breaching the spirit of the present disclosure. Designations common to the accompanying drawings are used to indicate identical or similar elements. It should be understood that elements and features of an embodiment can be advantageously combined in another embodiment without extra descriptions.

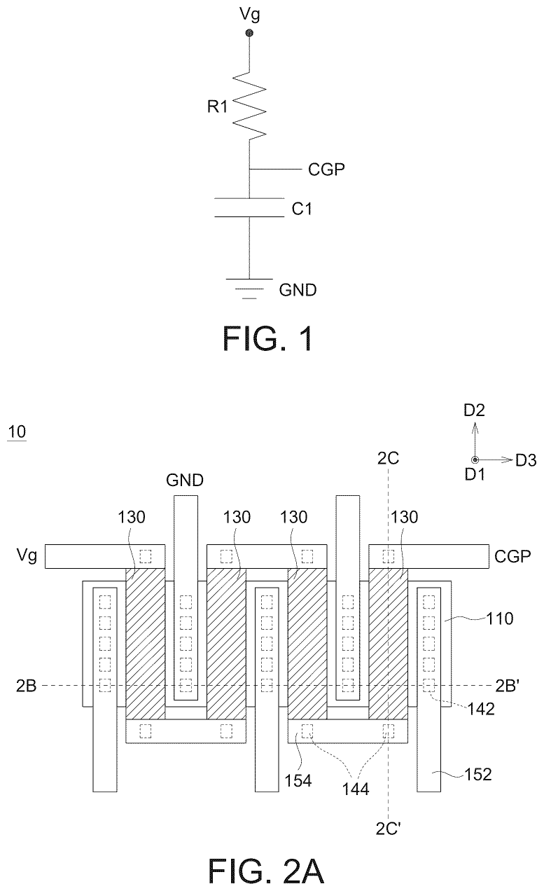

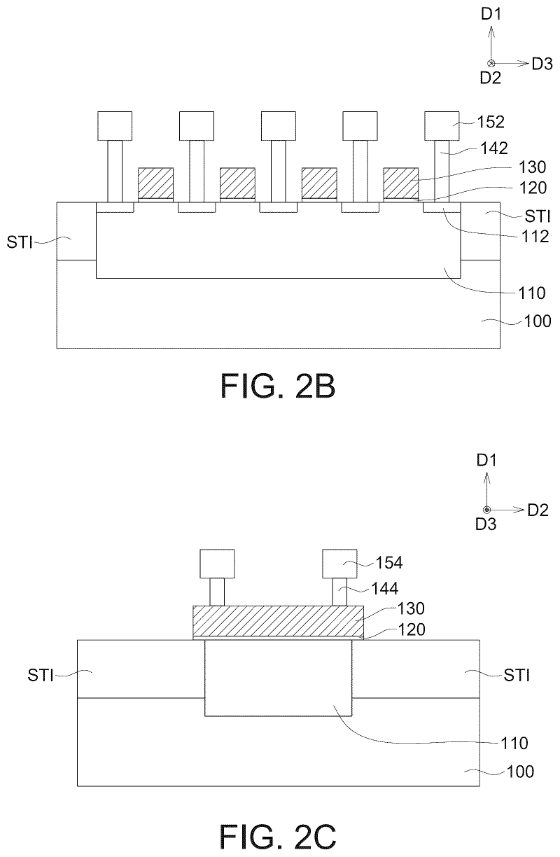

FIG. 1 is an equivalent circuit diagram of a semiconductor device 10 according to an embodiment of the present invention. FIG. 2A is a top view of a semiconductor device 10 according to an embodiment of the present invention. FIG. 2B is a cross-sectional view along the connection line 2B-2B′ of FIG. 2A. FIG. 2C is a cross-sectional view along the connection line 20-2C′ of FIG. 2A.

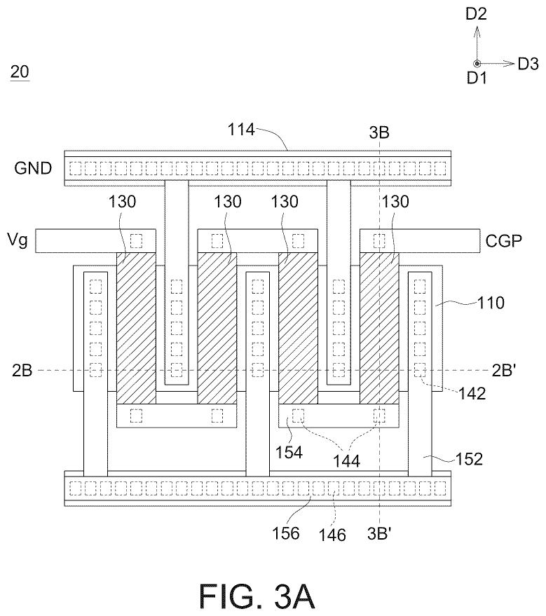

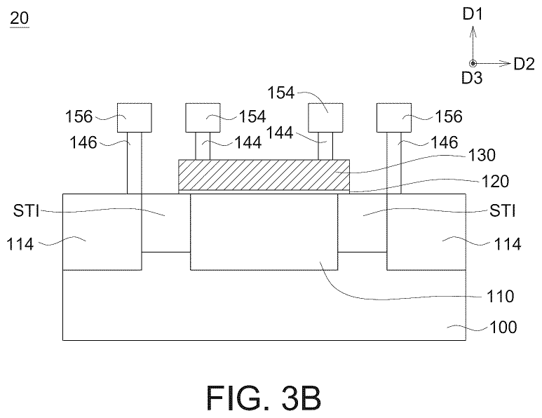

Refer to FIG. 1, the semiconductor device 10 includes a resistor R1 and a capacitor C1. One end of the resistor R1 is electrically connected to the common gate port GCP of a transistor (not illustrated). The other end of the resistor R1 is electrically connected to a DC biasing voltage Vg. The capacitor C1 is electrically connected to the ground GND. The capacitor C1 includes a top electrode, an insulation layer and a bottom electrode, wherein the insulation layer is disposed between the top electrode and the bottom electrode. The top electrode and the bottom electrode can be made of polycrystalline silicon, metal or other suitable conductive materials. The insulation layer can be made of oxide or other suitable insulating materials. That is, the capacitor C1 has a structure formed of top electrode—insulation layer—bottom electrode and corresponds to the structure of gate 130—oxide layer 120—substrate 100 as indicated in FIGS. 2A-3B (details are disclosed below).

Refer to FIGS. 2A and 2B. The semiconductor device 10 further includes a substrate 100, a first well 110, at least two doped regions 112, at least one gate 130 and at least one oxide layer 120. The substrate 100 serves as the bottom electrode of the capacitor C1. The substrate 100 can be realized by such as a P-type semiconductor substrate. The first well 110 is disposed in the substrate 100. The doped regions 112 are disposed in the first well 110 and are connected to the ground. The gate 130 is disposed on the substrate 100 and serves as the resistor R1 and the top electrode of the capacitor C1. The oxide layer 120 is disposed between the gate 130 and the substrate 100. The oxide layer 120 serves as the insulation layer of the capacitor C1. Thus, the resistor R1 and the capacitor C1 of the semiconductor device 10 share the gate 130, and the resistor R1 and the capacitor C1 are combined as a structure rather than being separated from each other.

In the present embodiment, the number of the at least one gate 130 is plural, the number of the at least one oxide layer 120 is plural, and the number of the doped regions 112 is greater than 2. However, in the present invention, the numbers of the gate 130, the oxide layer 120 and the doped regions 112 are not limited to the above exemplifications and can be adjusted according to actual needs. For instance, in another embodiment, the number of the gate 130 is 1, the number of the oxide layer 120 is 1, and the number of the doped regions 112 is 2.

As indicated in FIG. 2A-2B, the semiconductor device 10 further includes a plurality of first contacts 142, a plurality of first conductive layers 152 and an isolation structure STI. The first contacts 142 are connected to the doped regions 112. The first conductive layers 152 are connected to the first contacts 142, wherein the first contacts 142 are disposed on the doped regions 112, and the first conductive layers 152 are disposed on the first contacts 142. The isolation structure STI surrounds the first well 110. The isolation structure STI can be realized by a structure of shallow trench isolation, but the present invention is not limited thereto. In some embodiments, the semiconductor device 10 further includes a second well (not illustrated) formed in the substrate 100 and separated from the first well 110. The doped regions 112 are electrically connected to the ground GND through the first contacts 142 and the first conductive layers 152.

As indicated in FIGS. 2A and 2C, the semiconductor device 10 further includes a plurality of second contacts 144 and a plurality of second conductive layers 154 connected to the second contacts 144, wherein the second contacts 144 are disposed at the terminal ends of the gates 130 (such as two opposite ends), and the second conductive layers 154 are disposed on the second contacts 144 so as to be electrically connected to the gates 130. In the present embodiment, the gates 130 are electrically connected to each other, such as connected in series, through the second conductive layers 154 and the second contacts 144 to form a resistor R1. One end of the gates 130 serving as the resistor R1 is electrically connected to the common gate port GCP of a transistor (not illustrated) through the second conductive layers 154 and the second contacts 144, and the other end of the gate 130 serving as the resistor R1 is electrically connected to a DC biasing voltage Vg through the second conductive layers 154 and the second contacts 144.

In the present embodiment, the gates 130 are stacked on the substrate 100 along the first direction D1, the first conductive layers 152 respectively extend along the second direction D2, the second conductive layers 154 respectively extend along the third direction D3, and the first direction D1, the second direction D2 and the third direction D3 are different from one another. For instance, the first direction D1, the second direction D2 and the third direction D3 are perpendicular to each other. As indicated in the top view of FIG. 2A, the gates 130 and the second conductive layers 154 form an S-like structure. In an embodiment, the height of the second contacts 144 in the first direction D1 is less than the height of the first contacts 142 in the first direction D1, but the present invention is not limited thereto. As indicated in FIG. 2A, the first contacts 142 overlapping each other in the second direction D2 are connected to the same first conductive layer 152 so as to be electrically connected to the ground GND.

The doping concentration of the doped regions 112 is greater than the doping concentration of the first well 110. The doped regions 112 can be heavily doped and serve as the source or the drain. The first well 110 and the doped regions 112 can have identical conductivity type. For instance, both the first well 110 and the doped regions 112 are N-type or P-type. The first well 110 and the doped regions 112 can form an ohmic contact.

In some embodiments, as the length of the gate 130 is increased in the second direction D2, resistance will increase and capacitance will increase accordingly. Alternately, as the thickness of the gate 130 is reduced, resistance will increase. Moreover, as the number of the gates 130 grows, the gates 130 will be connected in series, resistance will increase and capacitance will be connected in parallel and increase accordingly. When the resistance of the resistor R1 increases and the capacitance of the capacitor C1 also increases, it is advantageous for the AC ground of common gate to be formed in a radio frequency (RF) circuit. The semiconductor device 10 of the present application can easily produce a large capacitance using a small-sized capacitor C1.

FIG. 3A is a top view of a semiconductor device 20 according to another embodiment of the present invention. FIG. 3B is a cross-sectional view along the connection line 3B-3B′ of FIG. 3A. One of the differences between the semiconductor device 20 and the semiconductor device 10 is that the semiconductor device 20 further includes a second well 114, a plurality of peripheral contacts 146 and a connection layer 156, and other identical or similar arrangements will not be described in detail. For instance, the cross-sectional view along a connection line 2B-2B′ indicated in FIG. 3A is the same as that indicated in FIG. 2B.

Refer to FIG. 3A-3B. The semiconductor device 20 further includes a second well 114, a plurality of peripheral contacts 146 and a connection layer 156. The second well 114 is disposed in the substrate 100, wherein the second well 114 is separated from the first well 110. For instance, the second well 114 and the first well 110 are separated by an isolation structure STI. The peripheral contacts 146 are disposed in the second well 114. The connection layer 156 is disposed on the peripheral contacts 146 and are electrically connected to the peripheral contacts 146. The connection layer 156 extends along the third direction D3 and is physically and electrically connected to a plurality of first conductive layers 152, so that the first well 110 and the second well 114 can be equipotential. The doped regions 112 (illustrated in FIG. 2B) are electrically connected to the ground GND through the first contacts 142, the first conductive layers 152, the peripheral contacts 146 and the connection layer 156. The second well 114 is electrically connected to the ground GND through the peripheral contacts 146 and the connection layer 156.

The first well 110 has a first conductivity type, the second well 114 has a second conductivity type, and the first conductivity type is different from the second conductivity type. In an embodiment, the first conductivity type is N-type, the second conductivity type is P-type; that is, the first well 110 is an N-type well, and the second well 114 is a P-type well. In another embodiment, the first conductivity type is P-type, and the second conductivity type is N-type; that is, the first well 110 is a P-type well, and the second well 114 is an N-type well. The second well 114 can be used to isolate the first well 110.

The semiconductor devices 10 and 20 of the present invention can be used in a common-gate amplifier.

In comparison to the semiconductor device in which the resistor and the capacitor are separated from each other, in the semiconductor device of the present invention, the gate serves as a resistor and the top electrode of a capacitor and allows the resistor and the capacitor to be combined in a varactor, therefore the area/volume occupied by the resistor and the capacitor can be reduced. Moreover, in comparison to the semiconductor device of the comparison example which includes a large-sized capacitor (such as MIMCAP, MOMCAP or other capacitor), in the semiconductor device of the present invention, the oxide layer serves as the insulation layer of the capacitor and has a smaller thickness, therefore the size of the capacitor can also be reduced. That is, in the semiconductor device of the present invention, the resistor and the capacitor can be combined and the capacitor occupies a smaller area/volume, therefore the size of the semiconductor device can be greatly reduced, the area/volume of the RF passive device can be minimized, and the cost can be greatly reduced.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A semiconductor device, comprising a resistor and a capacitor, wherein the capacitor comprises a top electrode and a bottom electrode, and the semiconductor device further comprises:
a substrate, wherein the substrate serves as the bottom electrode of the capacitor;
a first well disposed in the substrate;
at least two doped regions disposed in the first well, wherein the at least two doped regions are connected to ground;
at least one gate disposed on the substrate, wherein the gate serves as the resistor and the top electrode of the capacitor; and
at least one oxide layer disposed between the gate and the substrate.

2. The semiconductor device according to claim 1, further comprising at least two first contacts and at least two first conductive layers connected to the at least two first contacts, wherein the at least two first contacts are disposed on the at least two doped regions, and the at least two first conductive layers are disposed on the at least two first contacts.

3. The semiconductor device according to claim 2, wherein the at least one gate is plural, and the gates are electrically connected to each other.

4. The semiconductor device according to claim 3, further comprising a plurality of second contacts and a plurality of second conductive layers connected to the second contacts, wherein the second contacts are disposed at terminal ends of the gates, and the second conductive layers are disposed on the second contacts so as to be electrically connected to the gates.

5. The semiconductor device according to claim 4, wherein a height of the second contacts is less than a height of the at least two first contacts.

6. The semiconductor device according to claim 4, further comprising a second well disposed in the substrate, wherein the second well is separated from the first well.

7. The semiconductor device according to claim 6, further comprising a plurality of peripheral contacts and at least one connection layer, wherein the peripheral contacts are disposed on the second well, and the at least one connection layer is disposed on the peripheral contacts and is electrically connected to the peripheral contacts.

8. The semiconductor device according to claim 7, wherein the at least one gate is stacked on the substrate along a first direction, the at least two first conductive layers respectively extend along a second direction, the second conductive layers extend along a third direction, and the first direction, the second direction and the third direction are different from each other.

9. The semiconductor device according to claim 8, wherein the at least one connection layer extends along the third direction.

10. The semiconductor device according to claim 6, wherein the first well has a first conductivity type, the second well has a second conductivity type, and the first conductivity type is different from the second conductivity type.
